(19) United States
(12) Patent Application Publication
(10) Pub. No.: US 2012/0022828 A1
(43) Pub. Date: Jan. 26, 2012

(54) MONITORING A MICROGENERATOR CIRCUIT OF A ROTARY ENCODER DEVICE

(76) Inventors: Michael Schneider, Konstanz (DE); Jochen Wilhelmy, Erlangen (DE)

(21) Appl. No.: 13/262,505

(22) PCT Filed: Mar. 12, 2010
(86) PCT No.: PCT/EP2010/001595

§ 371 Date: Sep. 30, 2011

(30) Foreign Application Priority Data
Mar. 31, 2009 (DE) 102009015711.5

(51) Int. Cl. G06F 15/00; G01R 31/34

(52) U.S. Cl. 702/151; 324/765.01

(57) ABSTRACT

A rotary encoder device for scanning a rotatable shaft includes a microgenerator circuit, which converts the kinetic energy of the shaft into an electrical voltage, and a monitoring circuit, which is designed to output an error signal that indicates a malfunction of the microgenerator circuit. The error signal is issued when the electrical voltage meets a predetermined criterion with respect to a reference threshold.

### CROSS REFERENCE TO RELATED APPLICATIONS

This application is a United States National Phase application of International Application PCT/EP2010/001595 and claims the benefit of priority under 35 U.S.C. §119 of German Patent Application DE 10 2009 015711.5 filed Mar. 31, 2009, the entire contents of which are incorporated herein by reference.

### FIELD OF THE INVENTION

The present invention pertains to a rotary encoder (also known as a shaft encoder) device for scanning a rotatable shaft, which comprises a microgenerator circuit, in which the kinetic energy of the shaft is converted into an electrical voltage and which is monitored by a monitoring circuit.

### BACKGROUND OF THE INVENTION

Measuring devices such as rotary encoder devices are generally used for monitoring and controlling mechanical motion sequences. For example, rotary encoders are used for speed detection and control of motors, control or regulation of conveyor systems or monitoring of conveyor belts.

It is known in the state of the art to supply such rotary encoders equipped with electronic revolution counters with energy by means of generators as well as microgenerators.

In the state of the art, a microgenerator is known, which always triggers the generation of an electrical pulse when a moving body reaches a predeterminable position and which comprises the following components: 1. an energy storage means, which progressively collects and stores some of the kinetic energy of the body in the form of potential energy during the approach of the body at the predeterminable position, and on reaching the position, promptly releases the stored potential energy in the form of kinetic energy, 2. a device for converting this kinetic energy into an electrical pulse, and 3. a processing means, to which the electrical pulse is fed.

The kinetic energy is converted into an electrical pulse inductively or, for example, by means of piezoelectric transducer elements.

The problems arises hereby that a failure or a malfunction of the rotary encoder device may occur. If the circuit is supplied by an external voltage, the correct function of the microgenerator cannot be established. If, for example, there is damage to the microgenerator, such as a broken wire in a coil of the microgenerator, the revolutions are nevertheless counted correctly during the operation. If the drive, to which the revolution counter is attached, is turned off, for example, in an emergency stop with turning off of the external supply voltage of the rotary encoder device, and the drive completes a few revolutions until stopping, then these revolutions are not recognized in case of a failure of the microgenerator. After turning on again, the revolution counter supplies an incorrect value, without the failure of the microgenerator being able to be determined. Damage to the system, e.g., driving onto a limit, is possible. This also applies in case another component of the revolution counter, such as a non-volatile memory for storing position information and/or a microprocessor for processing the position information is not working correctly.

### SUMMARY OF THE INVENTION

Thus, a basic object of the present invention is to provide a measuring device, and especially a rotary encoder device, which has an increased reliability of the mode of operation of the measuring device.

The above-mentioned object is accomplished by the rotary encoder device for scanning a rotatable shaft, which comprises a microgenerator circuit, which converts the kinetic energy of the shaft into an electrical voltage, and a monitoring circuit, which is designed to output an error signal that indicates a malfunction of the microgenerator circuit, when the electrical voltage meets a predetermined criterion with respect to a reference threshold.

The electrical voltage may especially be a DC voltage, and the predetermined criterion may be that the DC voltage is below a reference DC voltage. The electrical voltage may also be an AC voltage, especially a voltage pulse, and in this case, the predetermined criterion may be that the width and/or height of the voltage pulse is below a predetermined threshold. The criterion may also refer to a threshold that values of the width/height of the voltage pulses integrated over a plurality of voltage pulses have to meet to meet the criterion. In another example, it is assumed that the microgenerator circuit converts kinetic energy of the shaft into an electric DC voltage.

The term shaft comprises herein a rotatable, purely mechanically or electrically drivable axle and likewise generally any rotatable, rectilinear, curvilinear or helical solid or hollow body, whose angle of rotation is detected by the rotary encoder device. The shaft may be, for example, a hollow shaft or solid shaft.

The term microgenerator circuit comprises herein a microgenerator and other suitable components. As it is well known in the state of the art, a microgenerator supplies a rotary encoder device with energy. Preferably, voltage pulses of the microgenerator will pass through a bridge rectifier in the microgenerator circuit and will be stabilized by means of a capacitor. The capacitor, as part of the microgenerator circuit, is thus typically charged by the voltage pulses and typically provides a stabilized DC voltage signal.

The term monitoring circuit comprises herein an electronic circuit with electronic components and circuit components, for example, with voltage regulators, each of which can supply an adjustable DC voltage as output voltage, and further, for example, with a microprocessor and a non-volatile electronic storage medium. Further, the monitoring circuit is suitable to evaluate the voltage signals output by the microgenerator circuit with respect to a malfunction of the microgenerator circuit.

The term reference DC voltage refers to a threshold voltage or minimum input voltage (see below). If this reference DC voltage, i.e., threshold voltage, is not exceeded, the monitoring circuit outputs an error signal, which indicates a malfunction of the microgenerator.

The microgenerator circuit is consequently effectively monitored by the monitoring circuit provided according to the present invention. A failure of the microgenerator circuit can especially be reliably detected, as a result of which the reliability of the information provided by the rotary encoder device about the rotation of the shaft is significantly increased compared to the state of the art.

Moreover, the monitoring circuit of the rotary encoder device may comprise a first voltage regulator, which provides an output voltage, U_{A}, based on the DC voltage supplied by the microgenerator circuit. Hereby, the DC voltage is supplied from the microgenerator circuit, which is preferably still stabilized by the capacitor, at the input of the first voltage regulator. This will then provide an output voltage, U_{A}, when a DC voltage is at an input of the voltage regulator that is greater than or equal to the reference DC voltage U_{R}. In this case, the reference DC voltage may itself preferably be selected such that the reference DC voltage, i.e., the threshold voltage or minimum input voltage, is greater than or equal to the output voltage, U_{A}, provided by the voltage regulator. Furthermore, it is advantageous when the output voltage of the first voltage regulator, U_{A}, can likewise preferably be suitably selected.

An error determination with respect to the function of the microgenerator circuit may also be done in a reliable manner with the monitoring circuit and specially by means of the first voltage regulator in that the first voltage regulator only supplies the output voltage U_{A} when a sufficient DC voltage is at the input of the first voltage regulator.

According to another variant, the rotary encoder device according to the present invention comprises a second voltage regulator, which is designed the supply a DC voltage to the monitoring circuit, and wherein the monitoring circuit is further designed to output the error signal based on an input voltage, U_{E}, which depends on the voltage supplied by the second voltage regulator and on the voltage supplied by the microgenerator circuit.

Furthermore, the DC voltage supplied by the second voltage regulator, i.e., the output voltage, U_{A2}, may drop via a component, and preferably via a diode, whereby a voltage drop, U_{D}, occurs, so that a resulting DC voltage, U_{A2}−U_{D}=U_{E}, is supplied to the monitoring circuit.

Furthermore, the resulting DC voltage U_{A2}−U_{D}, which is supplied to the monitoring circuit, may advantageously be smaller than the reference DC voltage, U_{R}, of the first voltage regulator.

For example, a DC voltage, the output voltage U_{A2}, is supplied by the second voltage regulator and is provided for supplying the monitoring circuit. As already with the first voltage regulator, the DC voltage U_{A2} may preferably be suitably selected. After a voltage drop, U_{D}, via a suitable component, for example, a diode, the resulting DC voltage is U_{A2}−U_{D}=U_{E}. By suitable selection of the output voltage U_{A2} and the voltage drop U_{D}, the resulting DC voltage is advantageously below the reference DC voltage, U_{R}, for the first voltage regulator, i.e., U_{E}<U_{R}. The output voltage of the first voltage regulator, U_{A}, is equal to U_{E}, when U_{E} is smaller than U_{R}. The resulting DC voltage U_{A2}−U_{D} may be considered to be a base DC voltage that is at least available for supplying the monitoring circuit regardless of the DC voltage that is provided by the microgenerator circuit. The resulting DC voltage is also especially available for supplying when the microgenerator circuit does not supply any voltage or supplies a too-low voltage, for example, when the shaft is not rotating, or for example, in the resting state of the microgenerator circuit, or in case of a broken wire within the microgenerator circuit or other electrical or mechanical defects of the microgenerator circuit. The input voltage, U_{E}, in contact with the input of the first voltage regulator is composed, for example, of two parts. Thus, it is advantageously the rectification of the DC voltage supplied by the second voltage regulator and the DC voltage supplied by the microgenerator circuit. The part of the input voltage that is supplied by the second voltage regulator as base DC voltage, i.e., as the resulting DC voltage, is alone not sufficient to exceed the reference DC voltage U_{R} of the first voltage regulator. Thus, it additionally requires the DC voltage supplied by the microgenerator circuit, so that the input voltage exceeds the reference DC voltage. In this case, U_{A} is equal to U_{R}.

In this variant, especially the error-free function of the microgenerator circuit with simultaneous external energy supply of the rotary encoder device can be controlled in a permanent and defined manner.

Furthermore, the monitoring circuit may comprise a microprocessor and a non-volatile electronic storage medium, especially a FeRAM, whereby the microprocessor is designed to determine a count based on the detection of the rotation of the shaft, and the non-volatile electronic storage medium is designed to store the count, whereby

the monitoring circuit further comprises a control line and a write access lock for the non-volatile electronic storage medium and is designed to release the write access lock via the control line for writing data onto the non-volatile electronic storage medium only when the input voltage, U_{E}, at the input of the first voltage regulator is greater than the reference DC voltage, and wherein

the monitoring circuit is designed to compare the current angular position with the count from the non-volatile electronic storage medium and to output an error signal when the difference is greater than a predetermined threshold value.

The monitoring circuit of the rotary encoder device will detect a malfunction of the microgenerator, for example, by the difference between the first and second count being at least 2. The threshold value is thus selected preferably to be 2.

A non-volatile electronic storage medium makes it possible to reread, read back or repeatedly read information and data, and especially counts or meter values, from or by the non-volatile electronic storage medium. This may, for example, be necessary when the rotary encoder device was regularly turned off and is then started again, or when an error condition has occurred. A write access lock typically controls whether and when data shall be written onto the non-volatile electronic storage medium. This write access may especially be prevented when the input voltage, U_{E}, at the first voltage regulator is smaller than the reference DC voltage. Preferably, read accesses to the non-volatile electronic storage medium, i.e., reading from the non-volatile electronic storage medium, as the microprocessor may typically instruct it, do not depend on the write access lock and especially not on the current state of the write access lock, i.e., whether or not a write access is allowed at the moment.

In an additional variant, the monitoring circuit may be designed to monitor the proper execution of the program of the microprocessor by the microprocessor preferably being designed to count one counting step per quarter rotation of the shaft, quadrant, and to store it in the non-volatile electronic storage medium and to record for the current quadrant whether a valid counting step is carried out by checking for the entire duration of the determination of the count whether especially the input voltage, U_{E}, stabilized by the capacitor of the microgenerator circuit, is greater than the reference DC voltage, U_{R}, and further checking before each new counting step whether a valid counting step has taken place in the previous quadrant and outputting an error signal when the previous counting step was not valid.

In this case, the capacitor may preferably allow a stabilized input voltage, U_{E}, especially an input voltage stabilized in terms of time.

In order to monitor the proper execution of the program of the microprocessor in a suitable manner, it may further prove to be advantageous to provide a certain tolerance when deciding whether a counting step is recorded as valid. To increase this tolerance before recording a valid counting step, the microprocessor may therefore execute, for example, a waiting loop, while it is checked whether it is further signaled via the control line that the input voltage, U_{E}, of the first voltage regulator is greater than the reference DC voltage. This may also be considered, such that a sufficiently high DC voltage signal is supplied by the microgenerator circuit during the entire time that the microprocessor needs for executing its program.

Moreover, the monitoring circuit of the rotary encoder device may preferably be designed for another functional testing of one of its components, namely checking or monitoring the proper functioning of the non-volatile electronic storage medium. The thus designed monitoring circuit accomplishes this monitoring, for example, by the memory content of the non-volatile electronic storage medium being read back again after storing the first count and being compared with the count in the microprocessor and a malfunction of the non-volatile electronic storage medium being output, provided that there is a deviation between the count present in the microprocessor and the count read back again.

By means of this checking, errors during the storage may consequently additionally still be detected in the respective reading back from the non-volatile electronic storage medium in especially critical applications.

In another variant, the rotary encoder device according to the present invention comprises a microgenerator that comprises a piezoelectric element, which comprises a plate, which is arranged in such a way that a mechanical force is exerted onto the plate during the rotation of the shaft, so that this undergoes a deformation.

The piezoelectric element is a component, which is able to generate an electrical voltage (a voltage signal) by means of the well-known piezoelectric effect when a mechanical force acts on it. It may be embodied as a piezoelectric crystal or in the form of a piezoelectric ceramic material, and for example, lead-zirconate-titanate. The piezoelectric element may be a plate made of a piezoelectric crystal or piezoelectric ceramic material, to which electrodes are attached, at which a voltage forms by an electrical field, which is generated by applying a mechanical force to the plate by means of the piezoelectric effect. Furthermore, the piezoelectric element may, in principle, be embodied as a piezoelectric tube or as a bimorph.

By using a piezoelectric element, a continuous energy supply of the rotary encoder can be achieved. Especially, this piezoelectric energy source is not unloaded during the operation, as is the case with a once charged and then used battery. In addition, the energy supply can be achieved in a simple and cost-effective manner via a piezoelectric element with high reliability by the kinetic energy of the shaft to be measured itself being used and being utilized in an electrically converted form via the piezoelectric element.

Moreover, the rotary encoder device according to the present invention may have a piezoelectric element with a plate (and especially consisting of a piezoelectric crystal or a piezoelectric ceramic material) that is arranged in such a way that a mechanical force is exerted onto the plate during the rotation of the shaft, so that this plate undergoes a deformation, which is converted by means of the piezoelectric effect into a voltage that can, for example, be accessed via electrodes attached to the plate and be used to supply the rotary encoder device. The plate may advantageously be attached to a carrier, for example, a carrier plate. An especially simple and cost-effective embodiment of the energy supply via a piezoelectric element is possible by means of the plate.

For example, the rotary encoder device may comprise a carrier element that is connected to the shaft and is arranged in such a way that it deflects the plate with each full revolution of the shaft. This deflection may be carried out by the carrier element being in direct mechanical contact with a carrier (plate), to which the plate is attached, so that a mechanical force is exerted by the carrier element via the carrier onto the plate. The carrier element may especially be directly attached to the shaft.

It is understood that the monitoring of a microgenerator circuit according to the present invention may be also generally be used for a measuring device corresponding to the above description. Thus, further provided is:

a measuring device for determining the position and/or the angle of rotation of a body that carries out a translational and/or rotational motion;

a microgenerator circuit that converts the kinetic energy of the body into an electrical voltage, and especially a DC voltage, and

a monitoring circuit, which is designed to output an error signal that indicates a malfunction of the microgenerator circuit, when the electrical voltage meets a predetermined criterion with respect to a reference threshold, especially when the DC voltage is below a reference DC voltage.

The measuring device may especially have the above-described features of the rotary encoder device according to the present invention.

Further, a process for monitoring a microgenerator circuit of a rotary encoder device is provided with the steps:

outputting an electrical voltage signal, and especially a DC voltage signal, by the microgenerator circuit,

analyzing the electrical voltage signal, and especially the DC voltage signal, and

outputting an error signal that indicates a malfunction of the microgenerator circuit when the electrical voltage meets a predetermined criterion with respect to a reference threshold, especially when the DC voltage is below a reference DC voltage.

Further features and advantages of the present invention are described below with reference to the drawing, which only illustrates an exemplary embodiment and absolutely does not represent the entire scope of the present invention. It is understood that the features shown can be used in other combinations, as described in the examples, within the framework of the present invention. The various features of novelty which characterize the invention are pointed out with particularity in the claims annexed to and forming a part of this disclosure. For a better understanding of the invention, its operating advantages and specific objects attained by its uses, reference is made to the accompanying drawings and descriptive matter in which preferred embodiments of the invention are illustrated.

### BRIEF DESCRIPTION OF THE DRAWINGS

In the drawings:

FIG. 1 illustrates components of a rotary encoder device according to the present invention.

### DESCRIPTION OF THE PREFERRED EMBODIMENTS

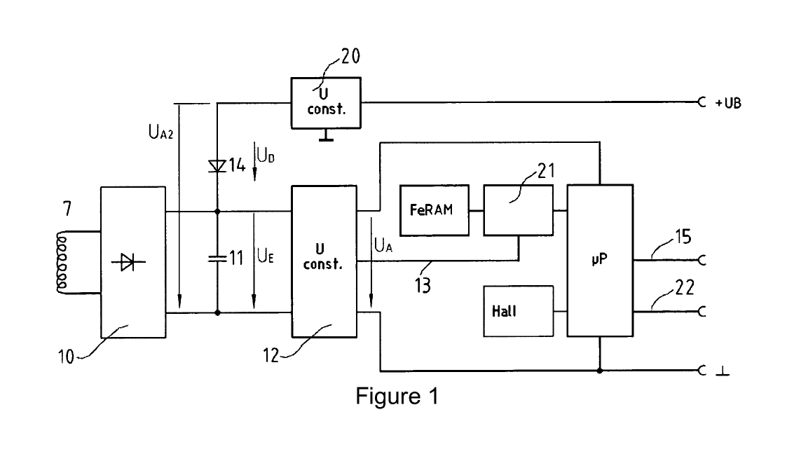

Referring to the drawings in particular, A microgenerator circuit with a microgenerator is monitored in an example by a monitoring circuit, as is shown in FIG. 1. The microgenerator may be, for example, such a one as is known from DE 103 55 859 or DE 43 42 069. The microgenerator may especially may have a piezoelectric element, as disclosed in the German patent application with application reference number 102008062849.2. The voltage pulses generated inductively in a coil (7) pass through a bridge rectifier (10), are then temporarily stored in a capacitor (11) and stabilized by a first voltage regulator (12) to the output voltage U_{A}. When the voltage U_{E} at the input of the first voltage regulator (12) exceeds U_{A}, this first voltage regulator (12) reports via a control line (13) to a microprocessor (μP) that its supply voltage is proper. If this is the case, the microprocessor receives the release to communicate with Hall sensors and a non-volatile memory (FeRAM).

The microgenerator supplies pulses at all speeds and changes in direction of rotation, even in the normal case when the revolution counter of the rotary encoder device is continuously supplied with energy via a diode (14) from the network. In this case, the microprocessor continues to work with no interruptions and always runs its processing cycle again until Hall sensors report a change in the shaft position. In case of a short-term failure of the external supply voltage, the voltage pulses of the microgenerator are available without interruption. This guarantees extraordinarily high reliability. The revolutions stored in a non-volatile storage medium, preferably a FeRAM, can be polled at an output (15) of the processor for further processing.

According to this example of the present invention, in case the monitoring circuit is supplied with outside energy, during normal operation an additional second voltage regulator (20) (see FIG. 1) supplies a voltage, U_{A2}, which has undergone a voltage drop, U_{D}, after the diode (14). In this case, U_{E}=U_{A2}−U_{D}<U_{A}, with which the minimum input voltage U_{E}≈U_{A} of the first (low-drop) voltage regulator (12) is not exceeded. If the microgenerator works properly, it supplies, at the input of the first voltage regulator (12), a voltage pulse U_{E}>U_{A} and the voltage regulator (12) releases a write access lock (21) via the control line (13) as long as the voltage pulse is applied. If the microgenerator fails, only the voltage U_{E}=U_{A2}−U_{D}<U_{A} is available at the input of the voltage regulator (12). This is smaller than the minimum input voltage of the voltage regulator (12). The voltage regulator (12) signals, on the control line (13), a too-low voltage to the write access lock (21), which then prevents an update of the count in the FeRAM. This case occurs not only in case of a broken wire of the microgenerator coil (7), but also when the shaft is not turning or in the resting state of the spring between two voltage pulses. An additional safety is achieved in this way, because the microprocessor can only access the FeRAM at exact points in time defined by the microgenerator. However, the count in the microprocessor (μP) does not itself depend on the write access lock, it can be further polled via the output (15).

With proper function of the microgenerator circuit, with shaft rotating at certain angular positions, voltage pulses are supplied by the microgenerator of the microgenerator circuit. The voltage pulses exceed the minimum input voltage of the first voltage regulator (12) and thus briefly release the write access lock (21) via the control line (13). The count newly calculated by the microprocessor can now be stored in the non-volatile memory.

If the microgenerator circuit fails, especially the microgenerator fails as well, and an update of the count in the FeRAM is prevented as a result of this; thus, a difference to the current count in the microprocessor (μP) is built up. If the difference is at least 2, this is a certain indication that a pulse of the microgenerator circuit, i.e., especially a pulse of the microgenerator, has not taken place. In this case, an error is signaled via an error output (22); however, regardless of this, the polling of the count updated in the microprocessor (R) continues to function via the output (15).

It has further emerged that it may be advantageous to monitor not only the presence of a voltage pulse of the microgenerator (i.e., the possible total failure of the microgenerator circuit), but that the height of the voltage pulse stored in the capacitor (11) and connected therewith the duration, over which the capacitor (11) can supply a sufficient voltage at the input of the first voltage regulator (12), is likewise of great importance for the proper function of the monitoring circuit and especially of the counting operation.

Foreign fields may especially have an effect on the microgenerators to the extent that the supplied voltage pulse is too small to charge the capacitor sufficiently to supply the electronic circuit with energy long enough until the counting operation of the monitoring circuit is properly concluded.

One approach to a solution may be to measure the height of the voltage pulse. If a comparator is used for this purpose, which measures the voltage at the capacitor (11), then the microgenerator is additionally stressed, either because it is also directly supplied by the microgenerator, or because current flows into a foreign supply via protection diodes of the comparator when this foreign supply is without current.

If, in an alternative solution, an analog-digital converter, an AD converter, which may be part of the microprocessor, is used to measure the voltage, then the voltage at the capacitor (11) must be reduced with a voltage divider, since, otherwise, the input voltage at the AD converter would be above the supply voltage of the microprocessor (μP). So that such a voltage divider does not stress the microgenerator considerably, it must be highly resistive, which, however, results in a high risk to external disturbing effects.

Another solution may be that the microprocessor itself monitors whether it can properly execute its program in the time, in which a sufficient voltage is signaled via the control line (13). This object is accomplished by the microprocessor (μP) detecting one counting step per quadrant and storing it in the non-volatile memory. The microprocessor (μP) thus typically rates the current counting step as valid when it can correctly execute its program, i.e., all steps that are connected to the counting operation. The result of this rating is thus additionally recorded. This may typically be carried out in a volatile memory integrated in the microprocessor (R). Before each new counting step, the microprocessor checks, based on the information now stored in volatile memory, whether a valid counting step was detected in the previous quadrant. If this is not the case because of the voltage signal being too small, the microprocessor (R) has thus been interrupted before conclusion of its program; this is detected by the microprocessor (μP) and output as an error.

To increase the safety in terms of tolerances, temperature and aging effects, the microprocessor (μP) executes a waiting loop, before recognizing a valid counting step, for the temporal extension of the duration, and checks whether a sufficient voltage is further signaled at the control line (13).

Another safety measure for monitoring the monitoring circuit itself is to monitor the non-volatile memory (FeRAM) in its proper functioning. This is achieved in that, after storing a new counting step, the memory content is immediately read out again and is compared with the value in the microprocessor (R). Deviations are rated as erroneous FeRAM and are output as errors.

To achieve a further redundancy in the safety measures for monitoring, an agreement of measured values of a single-turn processor, which constantly has the current position of the shaft within one rotation, with those of the microprocessor (μP) may be checked within each quadrant. In this case, a quadrant is allowed a tolerance of +/−, since an absolute agreement of the transfer from one quadrant to the next in the single-turn processor and the microprocessor (μP) cannot be achieved. An error would be detected at the latest after half a revolution (i.e., two quadrants).

While specific embodiments of the invention have been described in detail to illustrate the application of the principles of the invention, it will be understood that the invention may be embodied otherwise without departing from such principles.

1. A rotary encoder device for scanning a rotatable shaft, the rotary encoder comprising:
a microgenerator circuit, which converts kinetic energy of the shaft into an electrical DC voltage; and
a monitoring circuit, which provides an output of an error signal that indicates a malfunction of the microgenerator circuit, when the electrical voltage meets a predetermined criterion with respect to a reference threshold wherein the DC voltage is below a reference DC voltage.

2. A rotary encoder device in accordance with claim 1, in which the microgenerator circuit converts the kinetic energy of the shaft into a DC voltage and in which the monitoring circuit further comprises a first voltage regulator, which provides an output voltage, UA, based on the DC voltage.

3. A rotary encoder device in accordance with claim 2, further comprising:
a second voltage regulator, which is designed to supply a DC voltage to the monitoring circuit; and wherein the monitoring circuit is further designed to output the error signal, based on an input voltage, UE, that depends on the voltage supplied by the second voltage regulator and on the voltage supplied by the microgenerator circuit.

4. A rotary encoder device in accordance with claim 3, wherein an output voltage, UA2, supplied by the second voltage regulator, drops via a diode, whereby a voltage drop, UD, occurs, so that a resulting DC voltage, UA2−UD, is supplied to the monitoring circuit.

5. A rotary encoder device in accordance with claim 3, wherein the output voltage, UA2, of the second voltage regulator is greater than the reference DC voltage of the first voltage regulator, and wherein the resulting DC voltage, UA2−UD, which is supplied to the monitoring circuit, is smaller than the reference DC voltage of the first voltage regulator.

6. A rotary encoder device in accordance with claim 4, wherein:
the monitoring circuit further comprises a microprocessor (g) and a non-volatile electronic storage medium (FeRAM), whereby the microprocessor (mP) is designed to determine a count based on the detection of the rotation of the shaft, and the non-volatile electronic storage medium (FeRAM) is designed to store the count;
the monitoring circuit further comprises a control line and a write access lock for the non-volatile electronic storage medium (FeRAM) and is designed to release the write access lock via control line for writing data onto the non-volatile electronic storage medium (FeRAM) only when the input voltage, UE, is greater than the reference DC voltage at the input of the first voltage regulator; and
the monitoring circuit is designed to calculate a difference between the current angular position and the count and to output an error signal when the difference is greater than a predetermined threshold value.

7. A rotary encoder device in accordance with claim 5, wherein a malfunction of the microgenerator circuit is recognized by the difference between the angular position and the count being at least 2.

8. A rotary encoder device in accordance with claim 2, wherein the microgenerator circuit, comprises a capacitor for stabilizing the DC voltage.

9. A rotary encoder device in accordance with claim 7, wherein the monitoring circuit is designed to monitor the proper execution of the program of the microprocessor (μP), by the microprocessor (μP) being designed to count a counting step per quarter rotation of the shaft, a quadrant, and to store the count in the non-volatile electronic storage medium (FeRAM) and to record for the current quadrant whether a valid counting step is carried out by checking during the entire duration of the determination of the count whether the input voltage, UE, of the first voltage regulator, especially the input voltage, UE, stabilized by the capacitor of the microgenerator circuit, is greater than the reference DC voltage, and further to check before each new counting step whether a valid counting step has taken place in the previous quadrant, and to output an error signal when the previous counting step was not valid.

10. A rotary encoder device in accordance with claim 8, in which the microprocessor (μP) is designed to execute a waiting loop for increasing the tolerance before recording a valid counting step, wherein during the waiting loop a check is made as to whether there is a further signal via the control line that the input voltage, UE, of the first voltage regulator is greater than the reference DC voltage.

11. A rotary encoder device in accordance with claim 8, wherein the monitoring circuit is further designed to monitor the proper functioning of the non-volatile electronic storage medium (FeRAM) by the memory content of the non-volatile electronic storage medium (FeRAM) being read back again after storing the count and being compared to the count in the microprocessor (μP) and by a malfunction of the non-volatile electronic storage medium (FeRAM) being output provided that there is a deviation between the count present in the microprocessor (μP) and the count read back again.

12. A rotary encoder device in accordance with claim 1 wherein the microgenerator circuit comprises a piezoelectric element, which comprises a plate, which is arranged in such a way that a mechanical force is exerted onto the plate when the shaft is rotated, so that undergoes a deformation, and which comprises a carrier element that is connected to the shaft and is arranged in such a way that the plate deflects with each full revolution of the shaft.

13. A rotary encoder device in accordance with claim 12, wherein the piezoelectric element comprises a carrier plate and a plate, attached thereto, made of a piezoelectric crystal or a piezoelectric ceramic material, whereby the carrier plate is attached to an inside of a housing of the rotary encoder device in such a way that the carrier element comes into mechanical contact with the carrier plate once per full revolution of the shaft.

14. A measuring device for determining the position and/or the angle of rotation of a body which executes a translational and/or rotational motion the measuring device comprising
a microgenerator circuit, which converts the kinetic energy of the body into an electrical DC voltage; and
a monitoring circuit, which is designed to output an error signal that indicates a malfunction of the microgenerator circuit, when the electrical voltage meets a predetermined criterion with respect to a reference threshold, when the DC voltage is below a reference DC voltage.

15. A process for monitoring a microgenerator circuit of a rotary encoder device the process comprising the steps of:
providing a microgenerator circuit, which converts kinetic energy of a angular rotation into an electrical DC voltage; and
a monitoring circuit, which provides an output of an error signal that indicates a malfunction of the microgenerator circuit;
outputting an electrical DC voltage signal, by the microgenerator circuit;
analyzing the electrical DC voltage signal; and
outputting an error signal that indicates a malfunction of the microgenerator circuit when the electrical voltage meets a predetermined criterion with respect to a reference threshold, when the DC voltage is below a reference DC voltage.

16. A rotary encoder device in accordance with claim 9, wherein the monitoring circuit is further designed to monitor the proper functioning of the non-volatile electronic storage medium (FeRAM) by the memory content of the non-volatile electronic storage medium (FeRAM) being read back again after storing the count and being compared to the count in the microprocessor (μP) and by a malfunction of the non-volatile electronic storage medium (FeRAM) being output provided that there is a deviation between the count present in the microprocessor (μP) and the count read back again.
